(19) United States
(12) Patent Application Publication
(10) Pub. No.: US 2012/0146817 A1
(43) Pub. Date: Jun. 14, 2012

(54) KEYBOARD DEVICE WITH ANTENNA FUNCTION

(75) Inventors: CHIA-LUN TANG, MIAOLI COUNTY (TW); CHUN-HUA CHEN, TAIPEI COUNTY (TW)

(73) Assignee: AUDEN TECHNO CORP., TAOYUAN COUNTY (TW)

(21) Appl. No.: 12/967,450

(22) Filed: Dec. 14, 2010

(51) Int. Cl. H03M 11/00; G06F 3/02

(52) U.S. Cl. 341/22; 345/168

(57) ABSTRACT

A keyboard device with antenna function includes a keyboard unit, an antenna unit, and a conductive unit. The keyboard unit includes a substrate structure, a plurality of movable key structures disposed on the substrate structure, and at least one fixing key structure disposed on the substrate structure. The antenna unit includes at least one flexible substrate positioned on a bottom surface of one of the movable key structures or a bottom surface of the fixing key structure and at least one antenna track disposed on the flexible substrate. The conductive unit includes at least two conductive structures connected electrically to the antenna track. Hence, the instant disclosure can not only own both key function and antenna function, but also be applied to miniaturization electronic product such as notebook.

### BACKGROUND OF THE INVENTION

1. Field of the Invention

The instant disclosure relates to a keyboard device, and more particularly, to a keyboard device with antenna function.

2. Description of Related Art

In a wireless communication system, such as a notebook computer or a mobile phone, an antenna is a component for transmitting and receiving electromagnetic waves. The way that an antenna is designed and the location that it is mounted in the system influences its radiation pattern, and the quality of signal transmission. Furthermore, how the antenna is configured in the system will have a great effect on the cost of manufacturing the whole system.

Referring to FIG. 1, a schematic view of a conventional notebook computer equipped with an embedded antenna is shown. A notebook computer 1a generally includes a liquid crystal display (LCD) 10a and a base module 11a. Two embedded antennas 12a are symmetrically configured to the center of the upper edge of the LCD 10a to enhance the antenna diversity. An RF coaxial cable 13a is provided as a feed-in line of the antenna 12a so that the RF signals can be transmitted between the antenna 12a and the wireless module 14a on the base module 11a. A sheet of shielding aluminum foil 15a is electrically connected with the antenna 12a to improve the antenna radiation performance.

However, the above-mentioned structure of the antenna 12a equipped with the RF coaxial cable 13a for transmitting RF signals at least includes some disadvantages, for example, as follows:

1. Insertion loss: for a 100-centimeter-long high quality RF coaxial cable in the market, the insertion loss is 2.9 dB as the RF signal frequency is at 2.4 GHz while the insertion loss is 4.7 dB as the RF signal frequency is at 5 GHz. Generally, the length of a RF coaxial cable used in the notebook computer is about 20 cm to 90 cm. Therefore, the insertion loss is about 0.58 dB to 2.61 dB as the RF coaxial cable transmits a 2.4 GHz signal while the insertion loss goes up to 0.94 dB to 4.23 dB as the RF coaxial cable transmits a 5 GHz signal. Owing to the insertion loss, the antenna radiation pattern has to be concentrated to provide enough antenna gain for transmitting signals to a given distance. As a result, the antenna radiation angles will be reduced and the dead space (or the weak signal space) in communication will be increased, which directly reduces communication quality.

2. Cost increase: according to the general estimation conducted by antenna manufacturing industry, the above-mentioned RF coaxial cable occupies about 50% of the antenna manufacturing cost. Moreover, as the wireless system is fabricated, additional devices, such as hooks for fixing the RF coaxial cable and fixing pieces for fixing the shielding aluminum foil, are required to fix the RF coaxial cable, which further increases the cost. The labor hours for configuring and positioning the RF coaxial cable will largely increase the fabrication cost.

### SUMMARY OF THE INVENTION

One particular aspect of the instant disclosure is to provide a keyboard device having key function and antenna function at the same time.

To achieve the above-mentioned advantages, one embodiment of the instant disclosure provides a keyboard device with antenna function, including: a keyboard unit, an antenna unit, and a conductive unit. The keyboard unit includes a substrate structure and a plurality of movable key structures disposed on the substrate structure. The antenna unit includes at least one flexible substrate positioned on a bottom surface of one of the movable key structures and at least one antenna track disposed on the flexible substrate. The conductive unit includes at least two conductive structures connected electrically to the antenna track.

To achieve the above-mentioned advantages, one embodiment of the instant disclosure provides a keyboard device with antenna function, including: a keyboard unit, an antenna unit, and a conductive unit. The keyboard unit includes a substrate structure, a plurality of movable key structures disposed on the substrate structure, and at least one fixing key structure disposed on the substrate structure. The antenna unit includes at least one flexible substrate positioned on a bottom surface of the fixing key structure and at least one antenna track disposed on the flexible substrate. The conductive unit includes at least two conductive structures connected electrically to the antenna track.

To achieve the above-mentioned advantages, one embodiment of the instant disclosure provides a keyboard device with antenna function, including: a keyboard unit, an antenna unit, and a conductive unit. The keyboard unit includes a substrate structure, a plurality of movable key structures disposed on the substrate structure, and at least one fixing key structure disposed on the substrate structure. The antenna unit includes at least one flexible substrate positioned on a bottom surface of one of the movable key structures or a bottom surface of the fixing key structure and at least one antenna track disposed on the flexible substrate. The conductive unit includes at least two conductive structures connected electrically to the antenna track.

Therefore, antenna is integrated into key, thus the instant disclosure not only can own both key function and antenna function, but also can be applied to miniaturization electronic product such as notebook.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1 shows a perspective, schematic view of the notebook computer equipped with an embedded antenna according to the related art.

FIG. 2A shows a lateral, cross-sectional, schematic view of the keyboard device according to the first embodiment of the instant disclosure (before pressing key);

FIG. 2B shows a lateral, cross-sectional, schematic view of the keyboard device according to the first embodiment of the instant disclosure (after pressing key);

FIG. 2C shows one perspective, schematic view of the antenna track formed on the movable key structure according to the first embodiment of the instant disclosure;

FIG. 2D shows another perspective, schematic view of the antenna track formed on the movable key structure according to the first embodiment of the instant disclosure;

FIG. 2E shows a schematic view of another conductive unit according to the first embodiment of the instant disclosure (before pressing key);

FIG. 2F shows a schematic view of another conductive unit according to the first embodiment of the instant disclosure (after pressing key);

FIG. 3 shows a lateral, cross-sectional, schematic view of the keyboard device according to the second embodiment of the instant disclosure (before pressing key);

FIG. 4 shows a lateral, cross-sectional, schematic view of the keyboard device according to the third embodiment of the instant disclosure (before pressing key);

FIG. 5A shows a lateral, cross-sectional, schematic view of the keyboard device according to the fourth embodiment of the instant disclosure (before pressing key);

FIG. 5B shows a lateral, cross-sectional, schematic view of the keyboard device according to the fourth embodiment of the instant disclosure (after pressing key);

FIG. 5C shows a perspective, schematic view of the movable key structure or the fixing key structure being reversed according to the fourth embodiment of the instant disclosure;

FIG. 5D shows a partial, perspective, schematic view of the keyboard device according to the fourth embodiment of the instant disclosure;

FIG. 6 shows a partial, perspective, schematic view of the keyboard device according to the fifth embodiment of the instant disclosure;

FIG. 7 shows a lateral, cross-sectional, schematic view of the keyboard device according to the sixth embodiment of the instant disclosure (before pressing key); and

FIG. 8 shows a partial, exploded, schematic view of the keyboard device according to the seventh embodiment of the instant disclosure.

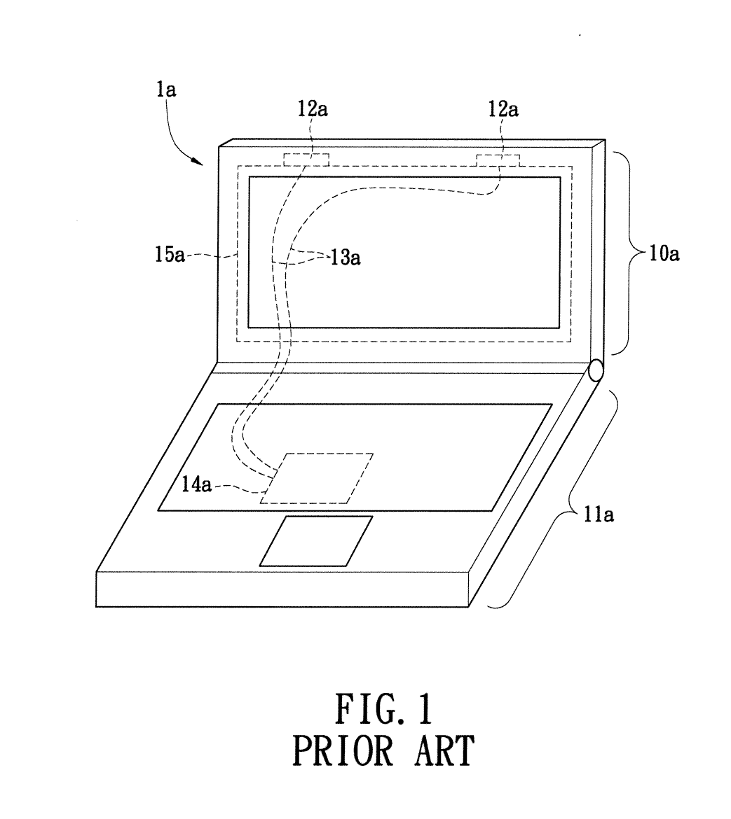

### DETAILED DESCRIPTION OF THE PREFERRED EMBODIMENTS

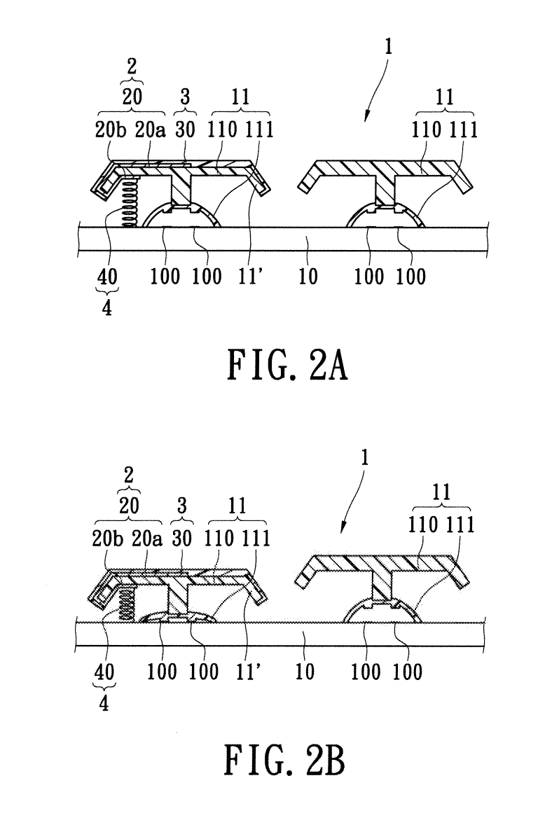

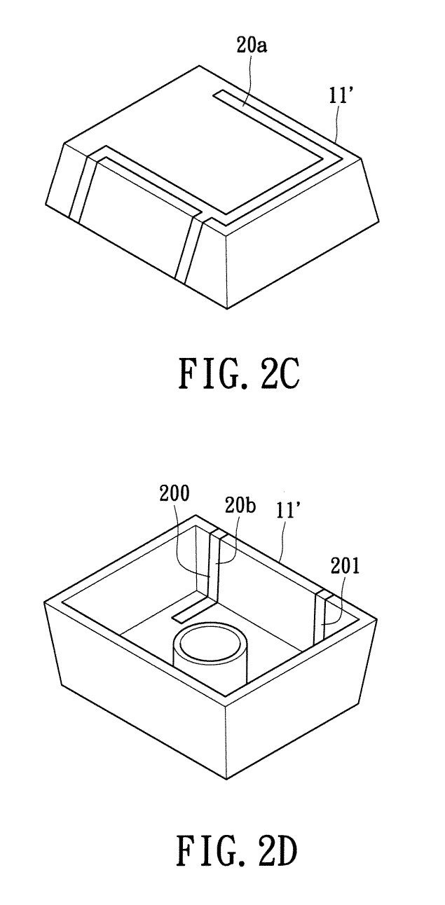

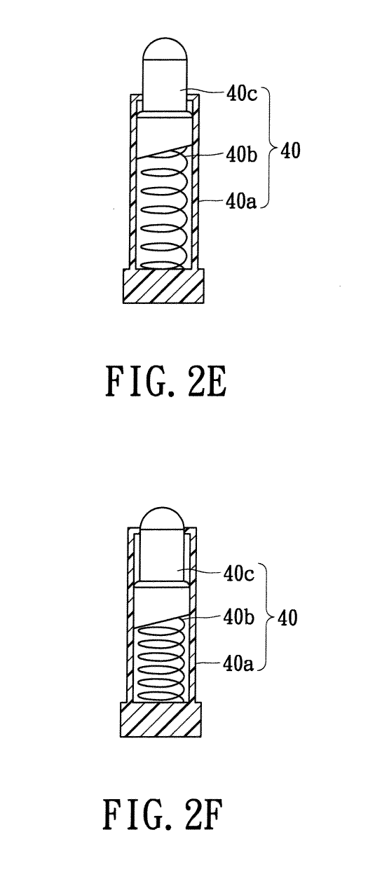

Referring to FIGS. 2A to 2D, where the first embodiment of the instant disclosure provides a keyboard device with antenna function, including a keyboard unit 1, an antenna unit 2, a shielding unit 3 and a conductive unit 4.

The keyboard unit 1 includes a substrate structure 10 and a plurality of movable key structures 11 operably disposed on the substrate structure 10. One of the movable key structures 11 is an antenna key structure 11′, and the antenna key structure 11′ can be any function key such as power on/off key or least used function key. For example, the substrate structure 10 has a plurality of conductive tracks 100 formed on the top surface thereof, and each movable key structure 11 includes a movable key body 110 and an elastic conductive structure 111 disposed on a bottom side of the movable key body 110 to selectively contact electrically every two conductive tracks 100 or separate from every two conductive tracks 100 (as shown in FIG. 2B).

However, the definition of each key structure 11 is just an example and not to limit the instant disclosure. Any type of key structure used to connect electrically every two conductive tracks 100 is protected in the instant disclosure.

The antenna unit 2 includes at least one antenna track 20 disposed on the antenna key structure 11′, and the antenna track 20 is divided into a first antenna portion 20a disposed on an outer surface of the antenna key structure 11′ and a second antenna portion 20b connected to the first antenna portion 20a and disposed on an inner surface of the antenna key structure 11′. For example, the first antenna portion 20a is disposed on the outer surface (or the top surface and the lateral surface) of the movable key body 110, and the second antenna portion 20b is disposed on the inner surface (or bottom surface).

The shielding unit 3 includes at least one shielding layer 30 (such as atomized layer or any opaque material layer) formed on the first antenna portion 20a for shielding the first antenna portion 20a, and the first antenna portion 20a can be covered by the shielding layer 30 by printing, spraying or any other forming methods. Because the shielding layer 30 is formed on the outer surface of the antenna key structure 11′ to cover the first antenna portion 20a, characters and symbols can be printed on the shielding layer 30 for user to recognize the function of the antenna key structure 11′.

The conductive unit 4 includes at least two conductive structures 40 electrically between the second antenna portion 20b and the substrate structure 10, for example, each conductive structure 40 may be an elastic element such as conductive spring. In addition, the antenna track 20 has a feeding pin 200 and a grounding pin 201 on end thereof, and the two conductive structures 40 are respectively connected electrically to the feeding pin 200 and the grounding pin 201 (as shown in FIG. 2D).

Referring to FIGS. 2E and 2F, the first embodiment of the instant disclosure provides another conductive structure 40 including a conductive casing 40a, an elastic element 40b received in the conductive casing 40a, and a movable element 40c connected to one end of the elastic element 40b for selectively projecting outward from the conductive casing 40a. For example, the movable element 40c can be positioned at a first position before pressing the movable element 40c (as shown in FIG. 2E) and the movable element 40c can be positioned at a second position after pressing the movable element 40c (as shown in FIG. 2F). Hence, the elastic element (the conductive structure 40) in FIG. 2A can be replaced by the conductive structure 40 in FIGS. 2E and 2F for connecting electrically the second antenna portion 20b and the substrate structure 10.

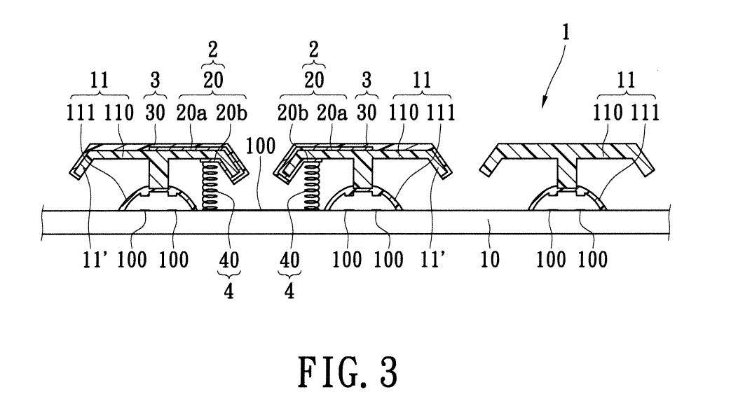

Referring to FIG. 3, the difference between the second embodiment and the first embodiment is that: the second embodiment provides at least two antenna key structures 11′, thus the instant disclosure does not limit the number of the antenna key structure. In other words, the antenna unit 2 can be disposed on one or more key structures 11, thus the instant disclosure can be operated for different frequency bands such as 2.4 and 5 GHz. In addition, every two antenna tracks 20 can be connected electrically to each other through conductive track 100 on the substrate structure 10.

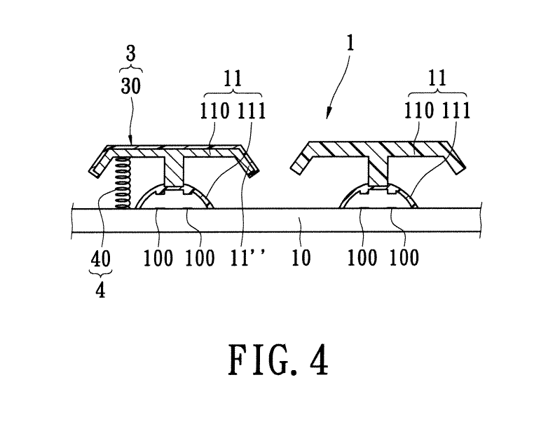

Referring to FIG. 4, where the third embodiment of the instant disclosure provides a keyboard device with antenna function, including a keyboard unit 1, a shielding unit 3 and a conductive unit 4. The difference between the third embodiment and the first embodiment is that: in the third embodiment, one of the key structures 11 is a metal key structure 11″ with antenna function, and the metal key structure 11″ can be made of any metal material. The shielding unit 3 has a shielding layer 30 formed on the outer surface (such as top surface and lateral surface) of the metal key structure 11′ for covering the metal key structure 11″. The conductive unit 4 has at least two conductive structures 40 connected electrically between the metal key structure 11″ and the substrate structure 10, for example, each conductive structure 40 may be an elastic element such as conductive spring. Of course, the shielding layer 30 can also be omitted for exposing the metal key structure 11″.

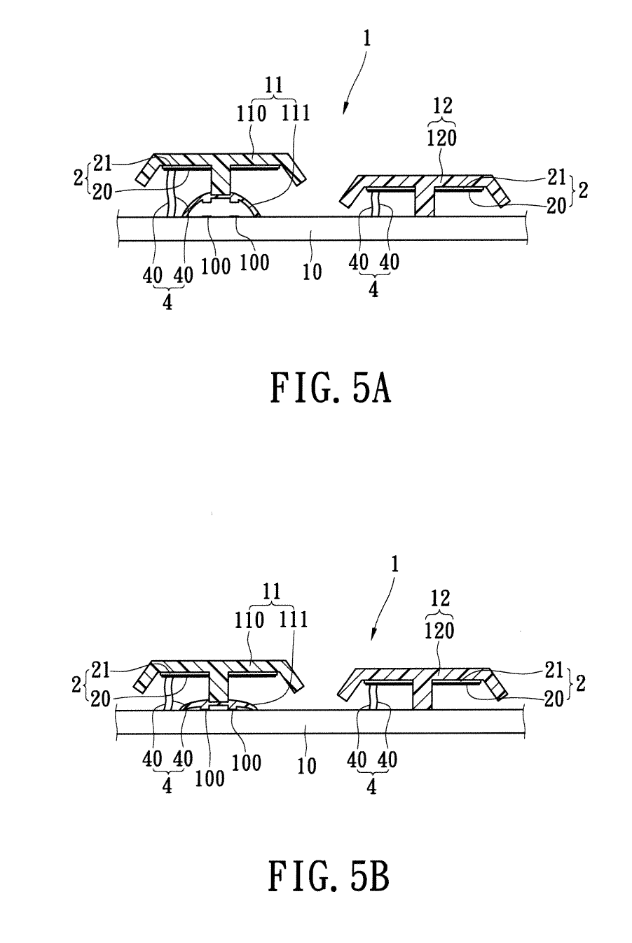

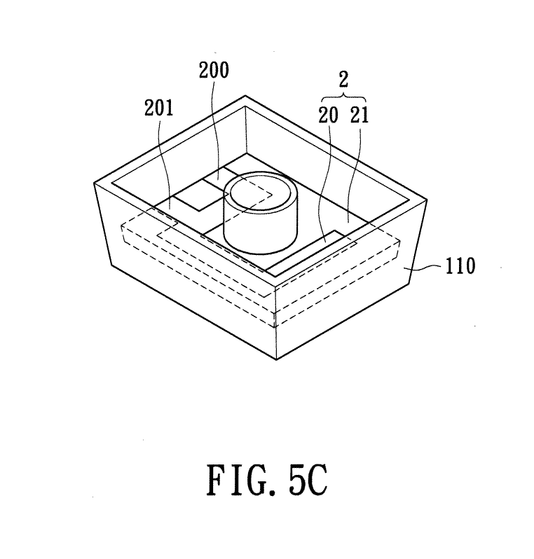

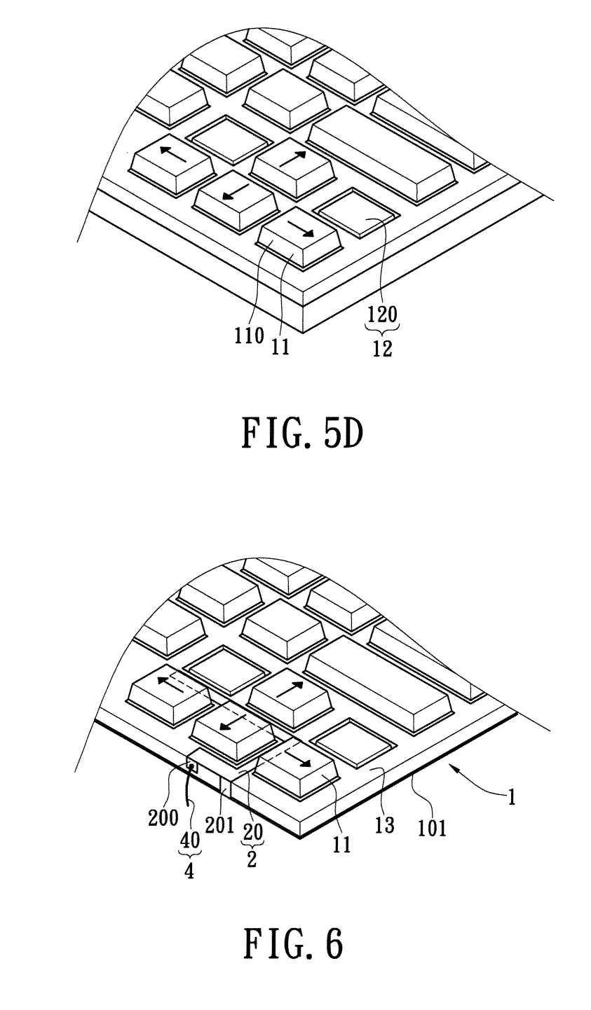

Referring to FIGS. 5A to 5D, where the fourth embodiment of the instant disclosure provides a keyboard device with antenna function, including a keyboard unit 1, an antenna unit 2, and a conductive unit 4.

The keyboard unit 1 includes a substrate structure 10, a plurality of movable key structures 11 disposed on the substrate structure 10, and at least one fixing key structure 12 disposed on the substrate structure 10. In addition, the substrate structure 10 has a plurality of conductive tracks 100 formed on the top surface thereof. Each movable key structure 11 includes a movable key body 110 and an elastic conductive structure 111 disposed on a bottom side of the movable key body 110 to selectively contact electrically every two conductive tracks 100 or separate from every two conductive tracks 100. The fixing key structure 12 includes a fixing key body 120 fixed on the substrate structure 10.

The antenna unit 2 includes at least one flexible substrate 21 positioned on a bottom surface of one of the movable key structures 11 or on a bottom surface of the fixing key structure 12 and at least one antenna track 20 disposed on the flexible substrate 21. In addition, the flexible substrate 21 is positioned on a bottom surface of the movable key body 110 or on a bottom surface of the fixing key body 120.

For example, in the fourth embodiment, the two flexible substrates 21 are respectively positioned on the bottom surface of one of the movable key structures 11 and the bottom surface of the fixing key structure 12, and the two antenna tracks 20 are respectively disposed on the two flexible substrates 21. Hence, the flexible substrate 21 can be positioned on the bottom surface of one of the movable key structures 11 and/or on the bottom surface of the fixing key structure 12 according to different requirements.

The conductive unit 4 includes at least two conductive structures 40 (such as conductive line or coaxial cable) connected electrically to the antenna track 20. For example, the antenna track 20 has a feeding pin 200 and a grounding pin 201 on end thereof (as shown in FIG. 5C), and the feeding pin 200 and the grounding pin 201 are respectively connected electrically to the substrate structure 10 (or wireless module (not shown) or any grounding source) through the two conductive structures 40. Hence, when the wireless module is built into a portable electronic device, the portable electronic device can receive and transmit wireless signals through the antenna unit 2.

For example, referring to FIGS. 5C and 5D, the movable key structures 11 can be arranged to form a predetermined shape, and the movable key structure 11 with the antenna unit 2 is the outermost one (as shown in FIG. 5D). Therefore, each conductive structure 40 can be extended downwardly along the lateral side of the keyboard device to connect electrically to wireless module or any grounding source.

For example, referring to FIGS. 5C and 5D, the movable key structures 11 are arranged to form a predetermined shape, and the fixing key structure 12 with the antenna unit 2 is disposed on an outermost position of the keyboard unit 1. Therefore, each conductive structure 40 can be extended downwardly along the lateral side of the keyboard device to connect electrically to wireless module or any grounding source.

Referring to FIG. 6, where the fifth embodiment of the instant disclosure provides a keyboard device with antenna function, including a keyboard unit 1, an antenna unit 2, and a conductive unit 4. The keyboard unit 1 includes a frame structure 13 and a plurality of movable key structures 11 passing through the frame structure 13. The antenna unit 2 includes at least one antenna track 20 formed on an outer surface of the frame structure 13. For example, the antenna track 20 has a feeding pin 200 and a grounding pin 201 on the end thereof. The feeding pin 200 can be connected electrically to the wireless module through the conductive structure 40 and the grounding pin 201 can contact a grounding layer 101 on the bottom side of the keyboard unit 1. Hence, when the portable electronic device with the wireless module can receive and transmit wireless signals through the antenna unit 2.

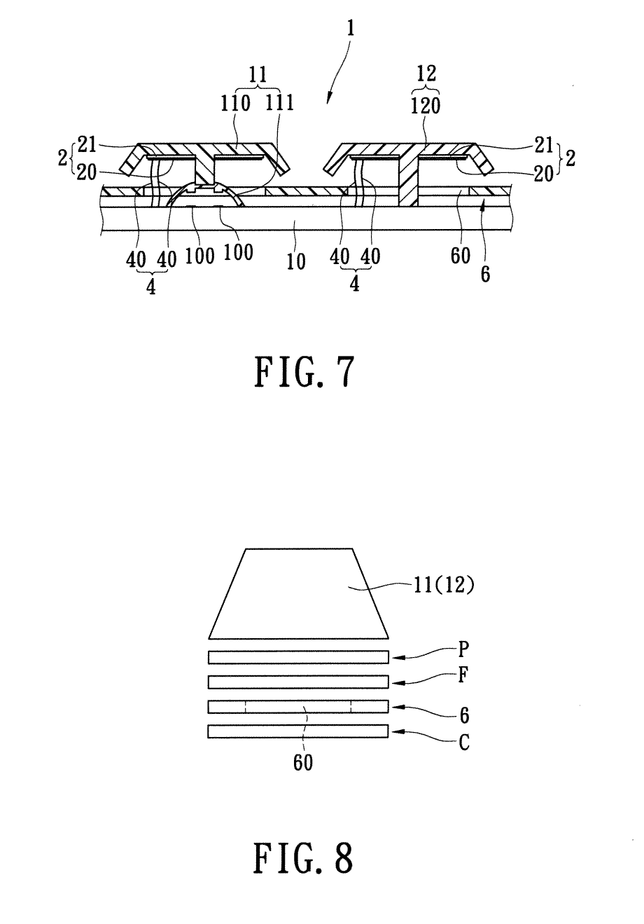

Referring to FIG. 7, where the sixth embodiment of the instant disclosure provides a keyboard device with antenna function, including a keyboard unit 1, an antenna unit 2, and a conductive unit 4. The keyboard unit 1 includes a substrate structure 10, a plurality of movable key structures 11 disposed on the substrate structure 10, and at least one fixing key structure 12 disposed on the substrate structure 10. The heights of each movable key structure 11 and the fixing key structure 12 are the same. In addition, the sixth embodiment further includes a plate body 6 having a plurality of through holes 60 (such as aluminium sheet with through holes), thus the conductive structures 40 can respectively pass through the through holes 60 to connect electrically to the conductive tracks 100 of the substrate structure 10.

Referring to FIG. 8, the seventh embodiment further includes a plastic washer P, a flexible PCB F for receiving key signals, a plate board 6 with many through holes 60, and a conductive layer C disposed under each movable key structure 11 in sequence. In addition, the antenna unit (not shown) is disposed on an inner surface of the movable key structure 11 or fixing key structure 12. The plate body 6 may be an aluminium sheet, and the conductive layer C may be a conductive aluminum foil. The plastic washer P, the flexible PCB F, the plate board 6 with the through holes 60, and the conductive layer C are stacked on bottom of each other in sequence. Hence, the conductive structures 40 can respectively pass through the through holes 60 to connect electrically to the conductive tracks 100 of the substrate structure 10.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A keyboard device with antenna function, comprising:
a keyboard unit including a substrate structure and a plurality of movable key structures disposed on the substrate structure;
an antenna unit including at least one flexible substrate positioned on a bottom surface of one of the movable key structures and at least one antenna track disposed on the flexible substrate; and
a conductive unit including at least two conductive structures connected electrically to the antenna track.

2. The keyboard device of claim 1, wherein the substrate structure has a plurality of conductive tracks formed on the top surface thereof, and each movable key structure includes a movable key body and an elastic conductive structure disposed on a bottom side of the movable key body to selectively contact electrically every two conductive tracks.

3. The keyboard device of claim 1, wherein each movable key structure includes a movable key body and an elastic conductive structure disposed on a bottom side of the movable key body, and the flexible substrate is positioned on a bottom surface of the movable key body.

4. The keyboard device of claim 1, wherein the antenna track has a feeding pin and a grounding pin on end thereof, and the feeding pin and the grounding pin are respectively connected electrically to the substrate structure through the two conductive structures.

5. The keyboard device of claim 1, wherein the movable key structures are arranged to form a predetermined shape, and the movable key structure with the antenna unit is the outermost one.

6. A keyboard device with antenna function, comprising:
a keyboard unit including a substrate structure, a plurality of movable key structures disposed on the substrate structure, and at least one fixing key structure disposed on the substrate structure;
an antenna unit including at least one flexible substrate positioned on a bottom surface of the fixing key structure and at least one antenna track disposed on the flexible substrate; and
a conductive unit including at least two conductive structures connected electrically to the antenna track.

7. The keyboard device of claim 6, wherein the substrate structure has a plurality of conductive tracks formed on the top surface thereof, and each movable key structure includes a movable key body and an elastic conductive structure disposed on a bottom side of the movable key body to selectively contact electrically every two conductive tracks.

8. The keyboard device of claim 6, wherein the fixing key structure includes a fixing key body fixed on the substrate structure, and the flexible substrate is positioned on a bottom surface of the fixing key body.

9. The keyboard device of claim 6, wherein the antenna track has a feeding pin and a grounding pin on end thereof, and the feeding pin and the grounding pin are respectively connected electrically to the substrate structure through the two conductive structures.

10. The keyboard device of claim 6, wherein the movable key structures are arranged to form a predetermined shape, and the movable key structure with the antenna unit is the outermost one.

11. A keyboard device with antenna function, comprising:
a keyboard unit including a substrate structure, a plurality of movable key structures disposed on the substrate structure, and at least one fixing key structure disposed on the substrate structure;
an antenna unit including at least one flexible substrate positioned on a bottom surface of one of the movable key structures or a bottom surface of the fixing key structure and at least one antenna track disposed on the flexible substrate; and
a conductive unit including at least two conductive structures connected electrically to the antenna track.

12. The keyboard device of claim 11, wherein the substrate structure has a plurality of conductive tracks formed on the top surface thereof, and each movable key structure includes a movable key body and an elastic conductive structure disposed on a bottom side of the movable key body to selectively contact electrically every two conductive tracks.

13. The keyboard device of claim 11, wherein each movable key structure includes a movable key body and an elastic conductive structure disposed on a bottom side of the movable key body, and the flexible substrate is positioned on a bottom surface of the movable key body.

14. The keyboard device of claim 11, wherein the fixing key structure includes a fixing key body fixed on the substrate structure, and the flexible substrate is positioned on a bottom surface of the fixing key body.

15. The keyboard device of claim 11, wherein the antenna track has a feeding pin and a grounding pin on end thereof, and the feeding pin and the grounding pin are respectively connected electrically to the substrate structure through the two conductive structures.

16. The keyboard device of claim 11, wherein the movable key structures are arranged to form a predetermined shape, and the movable key structure with the antenna unit is the outermost one.

17. The keyboard device of claim 11, wherein the movable key structures are arranged to form a predetermined shape, and the fixing key structure with the antenna unit is disposed on an outermost position of the keyboard unit.
